(19) United States
(12) Patent Application Publication
(10) Pub. No.: US 2017/0288131 A1
(43) Pub. Date: Oct. 5, 2017

(54) INTEGRATED HALL EFFECT SENSORS WITH VOLTAGE CONTROLLABLE SENSITIVITY

(71) Applicant: GLOBALFOUNDRIES Singapore Pte. Ltd., Singapore (SG)

(72) Inventors: Yongshun SUN, Singapore (SG); Eng Huat TOH, Singapore (SG); Kiok Boone Elgin QUEK, Singapore (SG)

(21) Appl. No.: 15/470,936

(22) Filed: Mar. 28, 2017

Related U.S. Application Data
(60) Provisional application No. 62/314,416, filed on Mar. 29, 2016.

(51) Int. Cl. H01L 43/06; G01R 33/07; G01R 33/00; H01L 43/14

(52) U.S. Cl. CPC H01L 43/065; H01L 43/14; G01R 33/07; G01R 33/0052; H01L 43/04

(57) ABSTRACT

An integrated Hall effect sensor is disclosed. The integrated Hall effect sensor has high tunable sensitivity by varying the thickness of the Hall plate. The Hall effect sensor is integrated onto a crystalline-on-insulator substrate, such as silicon-on-insulator (SOI) substrate. The Hall plate is part of the surface substrate of the SOI substrate. A sensor well is disposed in the bulk substrate of the SOI substrate. By applying an appropriate well bias voltage, the thickness of the Hall plate can be tuned from below the surface substrate to achieve the desired sensitivity. A gate may also be provided on the surface substrate. Biasing the gate with an appropriate gate bias voltage can further enhance thickness tunability of the Hall plate from above to achieve the desired sensitivity.

### BACKGROUND

Hall effect sensors have widespread applications. In particular, Hall effect sensors have numerous applications, such as in the automotive industry. As an example, Hall effect sensors may be used to sense the angular position of the crankshaft to determine the firing angle of the spark plugs, the position of the car seats and seat belts for air-bag control, or wheel speed detection for the anti-lock braking system (ABS).

The sensitivity of a Hall effect sensor depends on the Hall plate thickness. Conventional integrated Hall effect sensors are formed on a doped well, which is relatively thick. The thick doped well reduces the sensitivity of the Hall effect sensor.

The disclosure is directed to integrated Hall effect sensors which having highly tunable sensitivity.

### SUMMARY

Embodiments of the present disclosure generally relate to semiconductor devices. In one aspect, a device includes a crystalline-on-insulator (COI) substrate having a bulk crystalline substrate, a surface crystalline substrate and a buried oxide layer disposed between the bulk and surface crystalline substrates. The substrate includes a sensor region having a surface sensor region disposed on the surface crystalline substrate and a bulk sensor region disposed on the bulk crystalline substrate. A Hall effect sensor is disposed in the sensor region, and the Hall effect sensor includes a Hall plate in the surface sensor region. The Hall plate is part of the surface crystalline substrate. The Hall plate includes first and second current terminals which are configured to flow current through the Hall plate between the first and second current terminals in a length direction of the Hall plate. The Hall plate also includes first and second sensing terminals which are configured to sense a Hall voltage Vu along a width direction of the Hall plate which is perpendicular to the length direction. A predetermined thickness of the Hall plate is determined by a thickness of the surface crystalline substrate. A sensor well is disposed in the bulk sensor region in the bulk crystalline substrate. The sensor well includes a sensor well tap in the sensor well. The sensor well tap is coupled to a sensor well bias voltage for biasing the sensor well to vary a thickness of the Hall plate from the predetermined thickness of Hall plate to tune the sensitivity of the Hall effect sensor.

In another aspect, a method of forming a device is disclosed. The method includes providing a crystalline-on-insulator (COI) substrate having a bulk crystalline substrate, a surface crystalline substrate and a buried oxide layer disposed between the bulk and surface crystalline substrates. The substrate is prepared with a sensor region having a surface sensor region disposed on the surface crystalline substrate and a bulk sensor region disposed on the bulk crystalline substrate. A Hall effect sensor is formed in the sensor region. A Hall plate is formed in the surface sensor region. The Hall plate is part of the surface crystalline substrate and includes first and second current terminals configured to flow current through the Hall plate along a length direction of the Hall plate. The Hall plate also includes first and second sensing terminals which are configured to sense a Hall voltage Vu along a width direction of the Hall plate. The length and width directions are perpendicular directions. A predetermined thickness of the Hall plate is determined by a thickness of the surface crystalline substrate. A sensor well is formed in the bulk sensor region in the bulk crystalline substrate. A sensor well tap is formed in the sensor well. The sensor well tap is coupled to a sensor well bias voltage for biasing the sensor well to vary a thickness of the Hall plate from the predetermined thickness of Hall plate to tune the sensitivity of the Hall effect sensor.

These and other objects, along with advantages and features of the present invention herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIGS. 1a-1b show top and cross-sectional views of an embodiment of a device;

FIGS. 1c-1e show top views of various embodiments of a device;

FIGS. 2a-2b show top and cross-sectional views of another embodiment of a device;

FIGS. 2c-2e show top views of various embodiments of a device;

FIGS. 3a-3c show cross-sectional views of an embodiment of a process for forming a device; and

FIGS. 4a-4c show cross-sectional views of another embodiment of a process for forming a device.

### DETAILED DESCRIPTION

Embodiments generally relate to semiconductor devices or integrated circuits (ICs). More particularly, embodiments relate to ICs with embedded Hall sensors. The devices or ICs can be incorporated into or used with various products, such as automobiles and consumer electronic products.

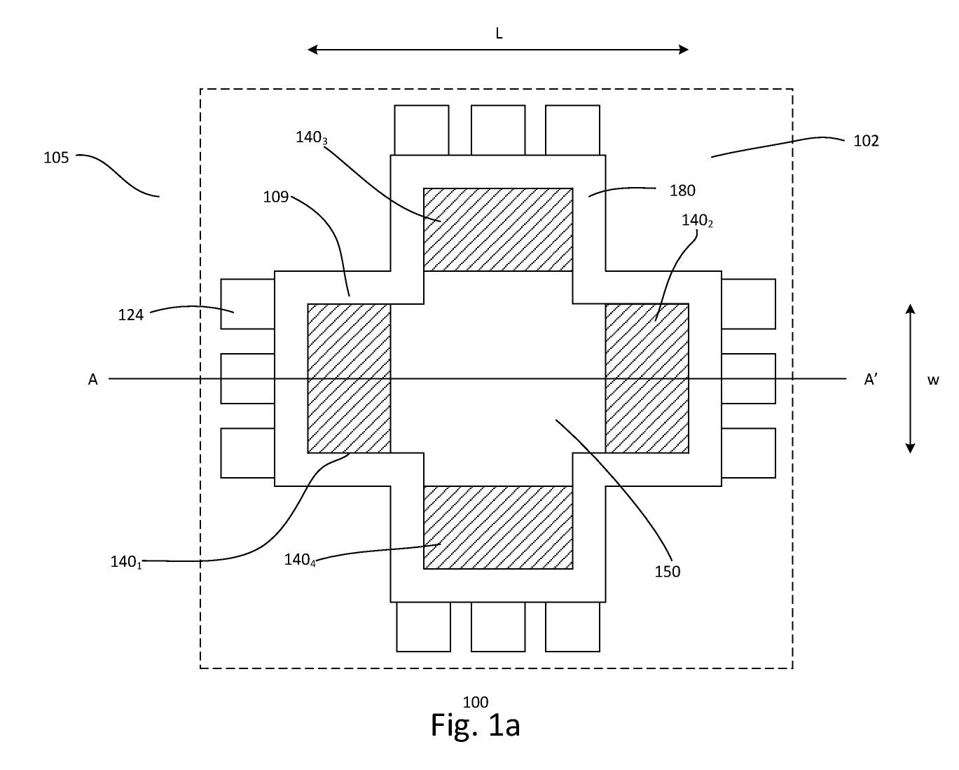

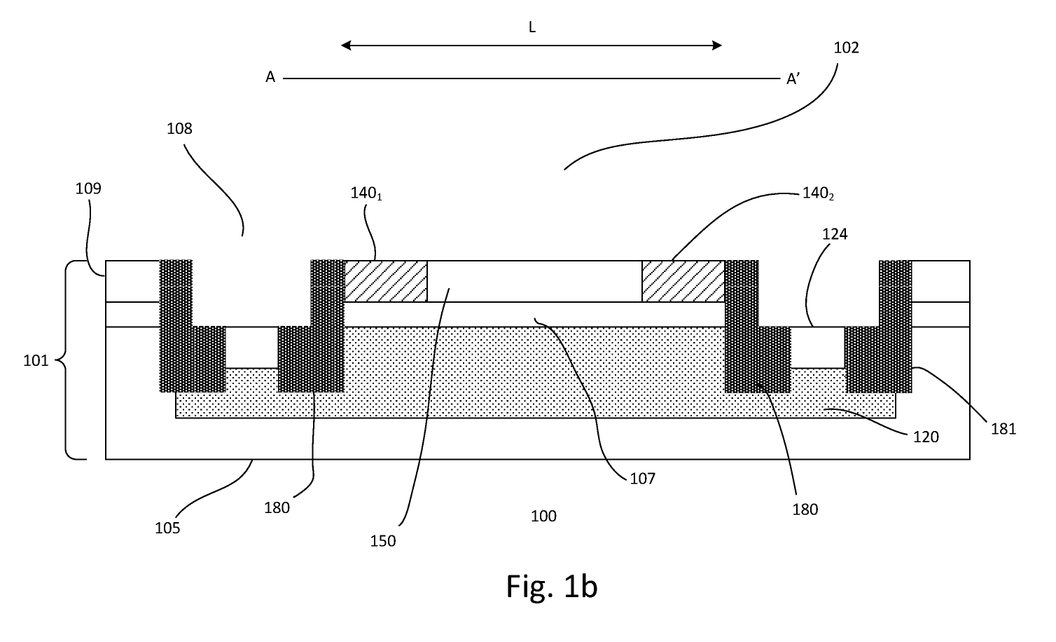

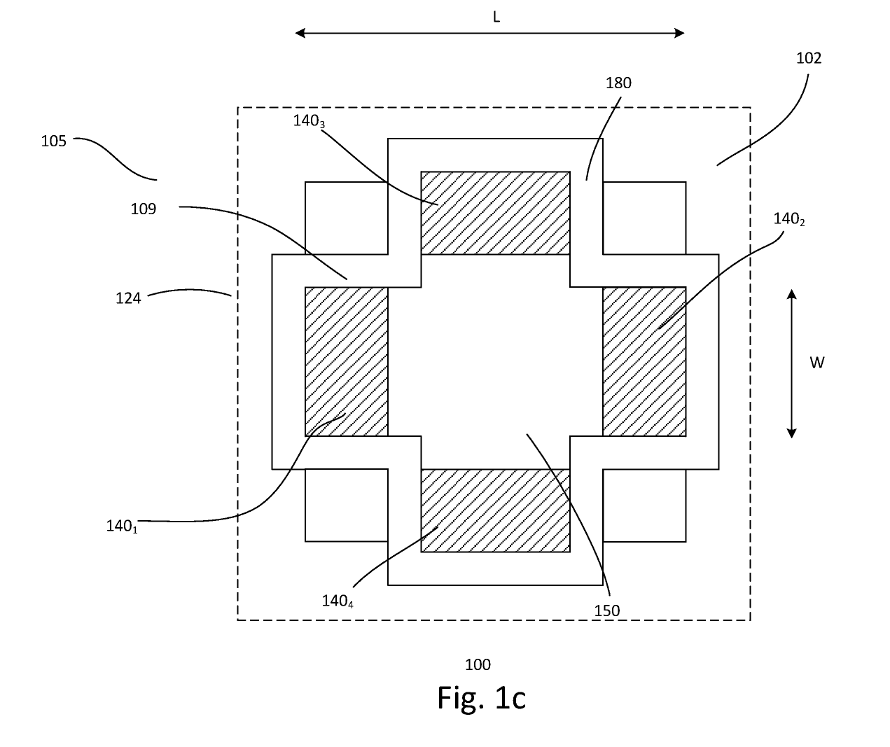

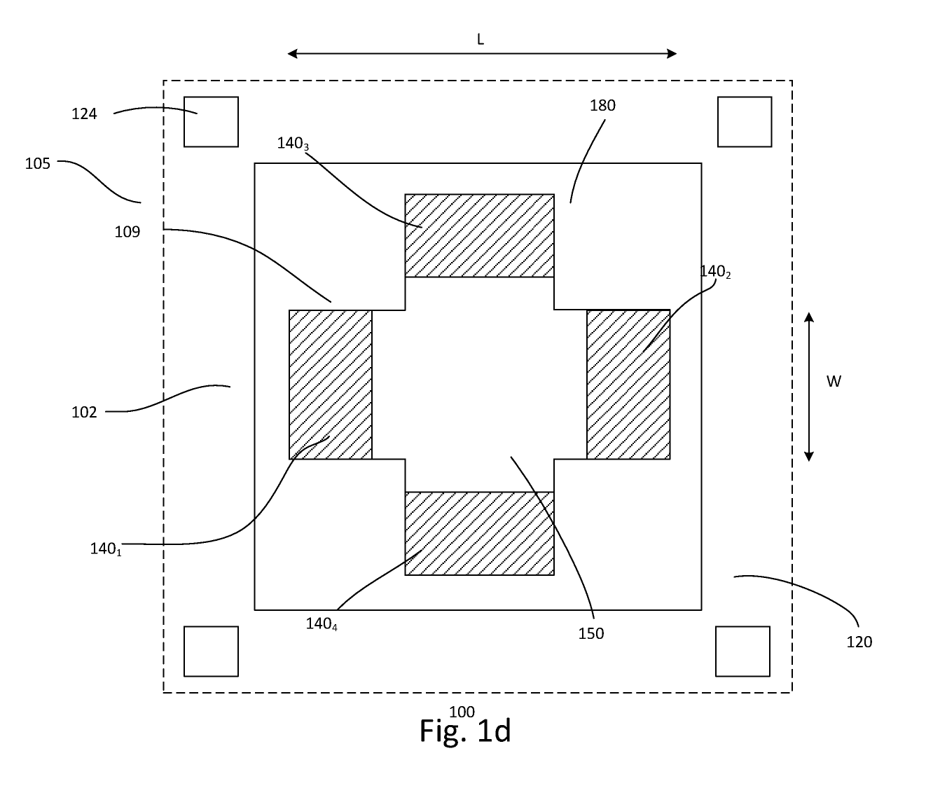

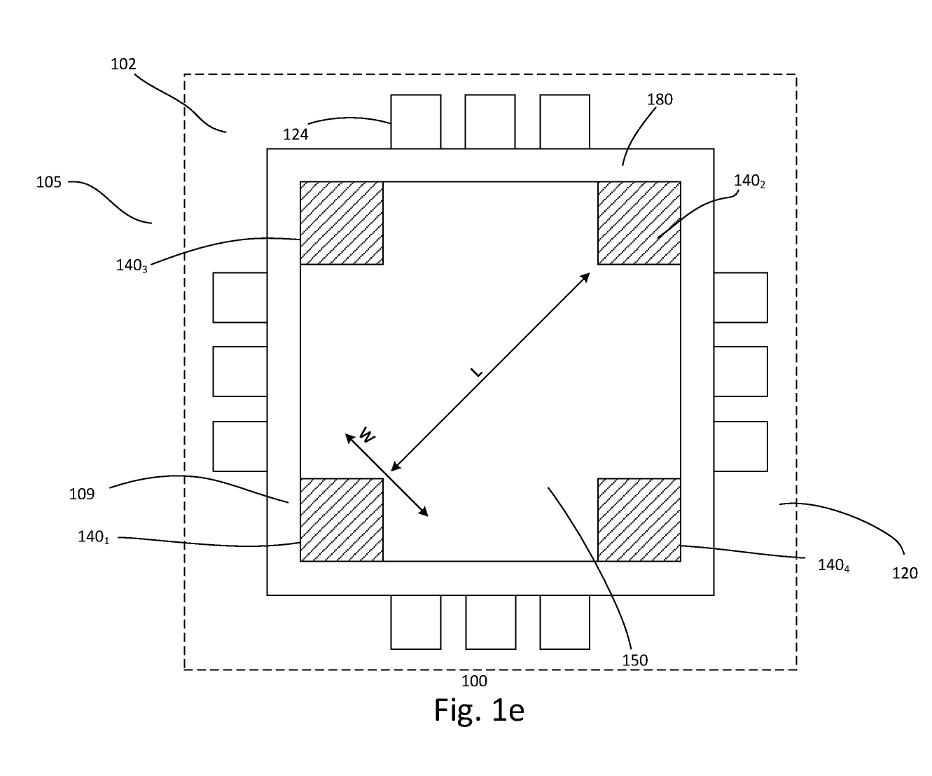

FIGS. 1a-1b show top and cross-sectional views of an embodiment of a device 100. The device, for example, is an integrated circuit (IC) embedded with a Hall effect sensor. Other types of devices may also be useful. The device may be formed in parallel on a wafer and subsequently be singulated. The device includes a substrate 101. The substrate may be a part of the wafer. In one embodiment, the substrate is a crystal-on-insulator (COI) substrate, such as a silicon-on-insulator (SOI) substrate. The COI substrate may be a fully depleted SOI (FDSOI) substrate. The COI substrate includes a silicon oxide layer 107 between a bulk crystalline substrate 105 and a surface crystalline substrate 109. The oxide layer may be referred to as a buried oxide (BOX) layer. The thickness of the surface substrate may be from about 5 nm-1 um while the BOX layer may be about 5-500 nm. Other thicknesses may also be useful. The bulk and surface substrates may be silicon, forming a SOI substrate. Other types of crystalline materials may also be useful. The substrates can be intrinsic or lightly doped, for example, with p-type dopants. Providing substrates with other types of dopants or dopant concentrations may also be useful.

The device may include doped regions having different dopant concentrations. For example, the device may include heavily doped (x⁺), intermediately doped (x) and lightly doped (x) regions, where x is the polarity type which can be p or n. A lightly doped region may have a dopant concentration of about 10¹⁶ to 10¹⁷ cm⁻³, an intermediately doped region may have a dopant concentration of about 10¹⁸ to 10¹⁹ cm⁻³, and a heavily doped region may have a dopant concentration of about 10²⁰ to 10²¹ cm⁻³. The doping concentrations, for example, are for 55 nm technology node. Providing other dopant concentrations for different doped regions may also be useful. For example, dopant concentrations may vary depending on, for example, the technology node. P-type dopants may include boron (B), aluminum (Al), indium (In) or a combination thereof, while n-type dopants may include phosphorous (P), arsenic (As), antimony (Sb) or a combination thereof.

As shown, the substrate includes a sensor region. The sensor region is configured for a Hall effect sensor 102. The sensor region occupies the surface substrate (surface sensor region) and the bulk substrate (bulk sensor region). The sensor region may include a hybrid sensor region 108 which exposes the bulk substrate in the bulk sensor region. The substrate may include other device regions. For example, the substrate includes complementary metal oxide semiconductor (CMOS) regions. The CMOS regions may occupy the substrate outside of the sensor region or sensor regions. The CMOS regions, depending on the design requirements, may occupy the bulk substrate, the surface substrate or both the surface and bulk substrates. The CMOS regions need not all to be the same.

The CMOS regions are not shown in detail. The CMOS regions may include MOS transistors, such as p-type and n-type MOS transistors. The CMOS regions may include various types of device regions for different types of MOS transistors, such as low voltage (LV) regions for low voltage MOS transistors, medium voltage (MV) regions for medium voltage MOS transistors, and high voltage (HV) regions for high voltage MOS transistors. The device may also include other device regions, such as a memory region for memory devices. Other types of components or device regions may also be useful.

As discussed, the substrate includes a hybrid sensor region 108. The hybrid region may surround the surface sensor region and may expose the substrate sensor region in the bulk substrate. The hybrid sensor region provides electrical connections to the bulk sensor region. The substrate may include other hybrid regions, such as CMOS hybrid regions. The hybrid CMOS regions expose the bulk substrate to provide electrical connections to bulk CMOS regions, such as CMOS wells, or, in some cases, to serve as a substrate for CMOS transistors. In some embodiment, core transistors may be formed on a surface substrate and input/output (I/O) transistors may be formed on the hybrid CMOS regions. The surface substrate may be a surface substrate of a FDSOI substrate.

As shown, the sensor includes a Hall plate 150 in the surface sensor region. The Hall plate is part of the surface substrate. The Hall plate, in one embodiment, has a cross shape or footprint. The cross-sectional view is along A-A′ of the top view. In one embodiment, the cross-sectional view is along the length direction of the Hall plate. In the case of the cross shape, the Hall plate includes four segments arranged in a cross configuration, with a central portion which serves as an intersection. As shown, the segments are symmetrical. For example, the segments may have the same dimensions, such as width, length, and a predefined thickness. The predefined thickness may be the thickness of the surface substrate. Not all segments of the Hall plate need to be symmetrical segments. The Hall plate may have other shapes or configurations.

The Hall plate may be an undoped or an intrinsic Hall plate. Alternatively, the Hall plate may be doped with Hall plate dopants, forming a doped Hall plate. In one embodiment, the Hall plate dopants are first polarity type dopants. The first polarity type dopants may be n-type dopants. In other cases, the first polarity type dopants may be p-type dopants. A doped Hall plate may be lightly or medium doped with Hall plate dopants. Preferably, a doped Hall plate is lightly doped with Hall plate dopants. First, second, third and fourth terminals or taps 1401, 1402, 1403 and 1404 are disposed at or near the ends of the Hall plate segments. The terminals are doped regions. In one embodiment, the terminals are heavily doped with terminal dopants. The terminal dopants may be first polarity type dopants. For example, the terminal dopants and Hall dopants are the same polarity type dopants. Metal silicide contacts (not shown) may be disposed over the terminal regions to reduce contact resistance.

Current is configured to flow through the Hall plate in the length direction. For example, current is configured to flow between the first and second terminals of the Hall plate. As for the third and fourth terminal, they are configured as sensing terminals of the Hall sensor. For example, the Hall sensor measures a voltage differential or Hall voltage (VH) between the third and fourth terminals. The length L of the Hall plate is between the first and second terminals of the Hall plate. The width W of the Hall plate is the width of the segments in the length direction.

The first and second terminals are described as current terminals for flowing current therebetween while the third and fourth terminals are sensor terminals. In some embodiments, the current and sensor terminals are interchangeable or alternate with time. For example, during operation, the first and second terminals may be current terminals while the third and fourth terminals may be sensor terminals. At another point in time, the current and sensor terminals are switched. For example, the first and second terminals may be sensor terminals while the third and fourth terminals are current terminals. Other configurations of terminals may also be useful.

Trench isolation regions 180 are disposed in the surface substrate. In one embodiment, the trench isolation regions include a surface sensor trench isolation region which surrounds the Hall plate. The surface sensor trench isolation region defines the surface sensor region on the surface substrate and BOX layer. The surface sensor trench isolation region, as shown, extends from a surface of the surface substrate and into the bulk substrate. The depth should be sufficient to provide the desired isolation in the bulk substrate. The top surface of the trench isolation region may be coplanar with the top surface of the surface substrate. In some embodiment, the trench isolation region may be slightly above the surface of the substrate. This may be due to a pad oxide which is part of a hard mask used to form the trench isolation regions. Other configurations of the surface of the trench isolation regions may also be useful. The surface substrate and BOX layer beyond the trench isolation are removed to expose the surface of the bulk substrate.

The trench isolation regions also include a hybrid sensor trench isolation region 181. The hybrid sensor trench isolation region defines a hybrid sensor region which exposes the bulk sensor region in the bulk substrate. As shown, the hybrid sensor trench isolation region and the sensor trench isolation region define the hybrid sensor region. The hybrid sensor isolation region surrounds the bulk sensor region in the bulk substrate. In one embodiment, the sensor trench isolation region and hybrid sensor trench isolation region are similar. For example, they extend from the surface substrate and into the bulk substrate. The sensor trench isolation region defines the bulk sensor region in the bulk substrate. As shown, the bulk sensor region in the bulk substrate has a larger footprint than the surface sensor region on the surface substrate. As shown, the trench isolation regions may have an L-shaped profile. The L-shaped profile is due to an overlapping etch mask to ensure that the hybrid region is defined.

Other trench isolation regions may also be included, such as CMOS and CMOS hybrid trench isolation regions. For example, the hybrid CMOS trench isolation regions may expose bulk CMOS regions to provide electrical connection. Other configurations of trench isolation regions may also be useful. The hybrid sensor trench isolation region may also be used to define a CMOS region disposed outside of the sensor region.

Disposed in the bulk sensor region is a sensor well 120. The sensor well is doped with sensor well dopants. The sensor well dopants may be either first or second polarity type dopants. For example, the sensor well dopants may be the same polarity type or of opposite polarity type as the Hall plate dopants. The polarity type of the sensor well dopants may be selected based on the design requirements, such as the isolation with other wells.

Sensor well taps 124 are provided. As shown, the sensor taps are disposed in the hybrid sensor region adjacent to the ends of the segments of the Hall plate. The exemplary embodiment illustrates 3 well taps disposed in the bulk substrate adjacent to ends of the segments. The well taps, for example, are aligned with the surface substrate isolation region. The sensor taps are heavily doped with well tap dopants. The well tap dopants are the same polarity type as sensor well dopants. For example, the well taps may be heavily doped with sensor well dopants.

The taps are coupled to a bias source for biasing the sensor well. Biasing the well causes a depletion region to form in the Hall plate. The thickness of the depletion region can be controlled by the magnitude of the bias voltage applied to the sensor well. Based on the bias voltage, the thickness of the predefined Hall plate can be varied by adjusting the thickness of the depletion region.

The Hall voltage VH is defined by Equation 1 as follows:

$${V}_{H} = \frac{I . B}{q . n . t} \qquad ( Equation 1 )$$

where

I=the current flowing through the Hall plate,

B=magnetic field,

q=1.6×10¹⁹ coulomb,

n=number of carriers which is related to the doping of the Hall plate, and

t=the thickness of the Hall plate.

Based on Equation 1, improved sensitivity is achieved with a thinner Hall plate.

An appropriate well bias voltage may be applied to the well taps to create a depletion region at the bottom of the Hall plate. Depending on the magnitude and polarity of the voltage, the depletion region may be adjusted to achieve the desired thickness for the Hall plate. For example, in the case of a p-type sensor well and n-type Hall plate, a voltage −Ve may be applied to bias the sensor well to create a depletion region. The bias voltage applied should avoid forward biasing the well with respect to other neighboring devices. The magnitude will determine the thickness of the depletion region, which then will define the thickness of the Hall plate. Decreasing the magnitude of the voltage will decrease the thickness of the depletion region, thereby increasing the thickness of the Hall plate. As such, the sensitivity of the Hall sensor can be controlled by the bias voltage on the sensor well.

FIGS. 1c-1e show top views of other embodiments of a Hall sensor. The cross-sectional views may be similar to FIG. 1b with minor modifications based on the top views. The top views may be similar to the top view of FIG. 1a. Common elements may not be described or described in detail. As shown in FIG. 1c, the Hall plate 150 is configured to have a cross shape. In contrast to FIG. 1a, the well taps 124 are disposed in the corner portions of the Hall plate formed by two adjacent segments. The well taps may be aligned by the surface substrate trench isolation region 180. Having well taps which are not aligned to the trench isolation region may also be useful.

Referring to FIG. 1d, the Hall plate 150 has a cross shape. The surface trench isolation region 180 has a rectangular shape surrounding the Hall plate. Well taps are disposed on the bulk substrate near the corners of the sensor well 120.

As for FIG. 1e, the Hall plate has a rectangular shape with terminals 1401, 1402, 1403 and 1404 disposed at the corners. The rectangular shape may be a square shape. The first and second terminals are disposed at opposite corners while the third and fourth terminals are disposed at the other opposite corners. The length direction is in the diagonal direction between the first and second terminals. The width direction is perpendicular to the length direction. A surface substrate trench isolation region 180 surrounds the Hall plate. Well taps are disposed on the bulk substrate for biasing the sensor well 120. The well taps, as shown, are aligned to the trench isolation region and disposed between the sensor terminals. Other configurations of well taps may also be useful.

The various top views illustrate various possible Hall plate shapes. Other Hall plate shapes may also be employed. In addition, the well taps may be arranged in different configurations as well. For example, there may be more or less well taps and arranged in different locations.

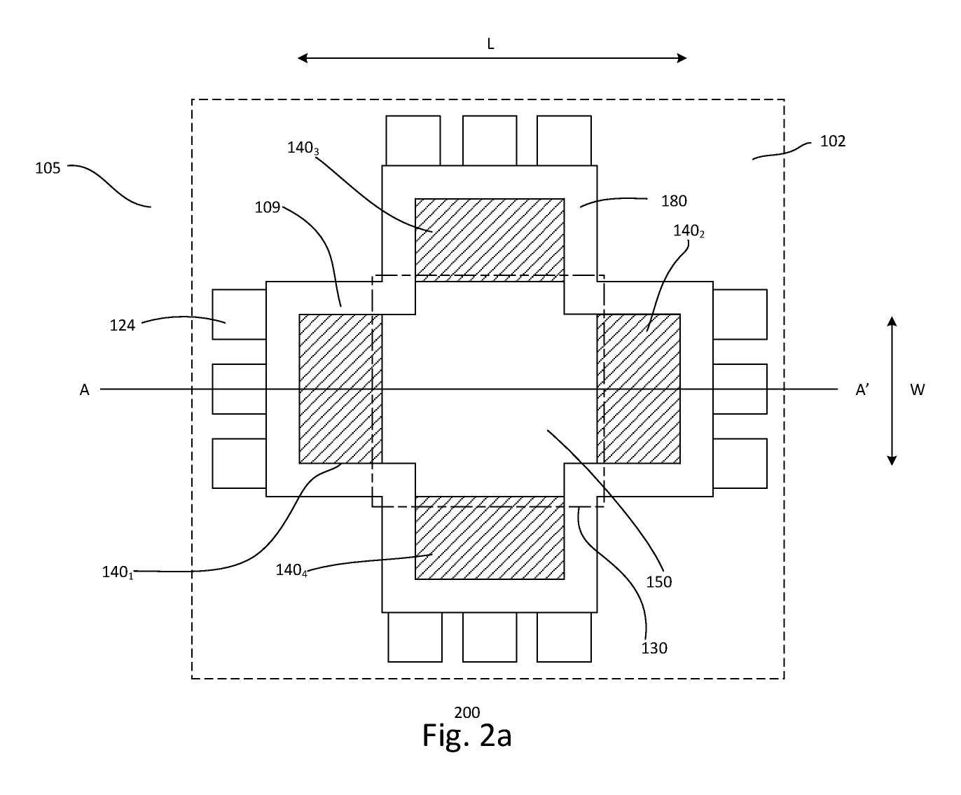

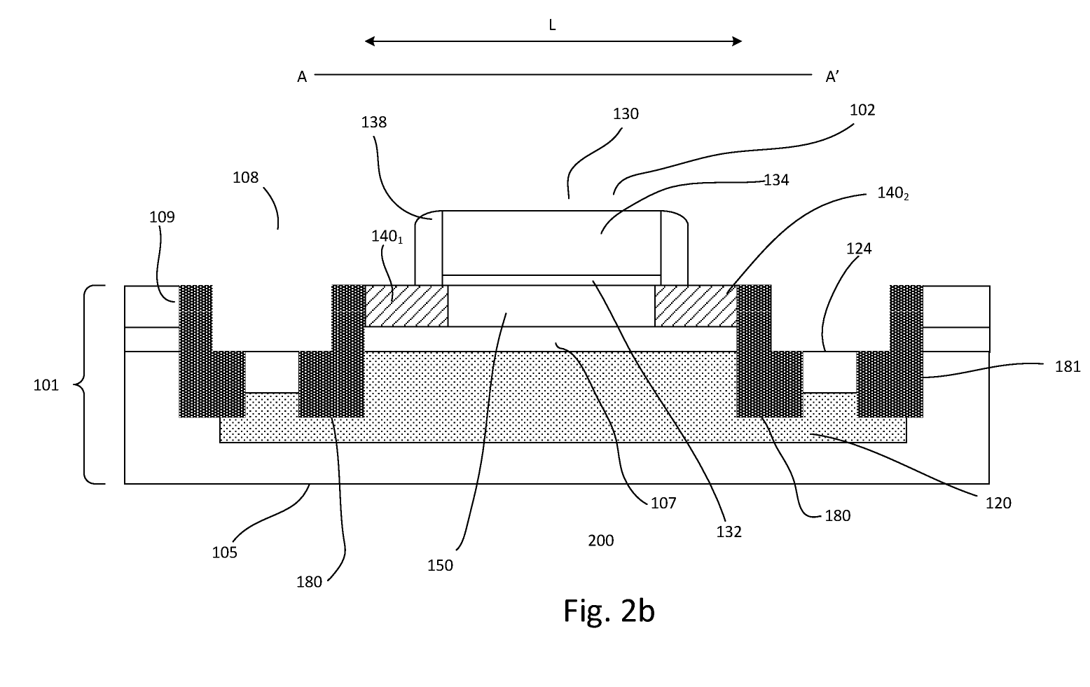

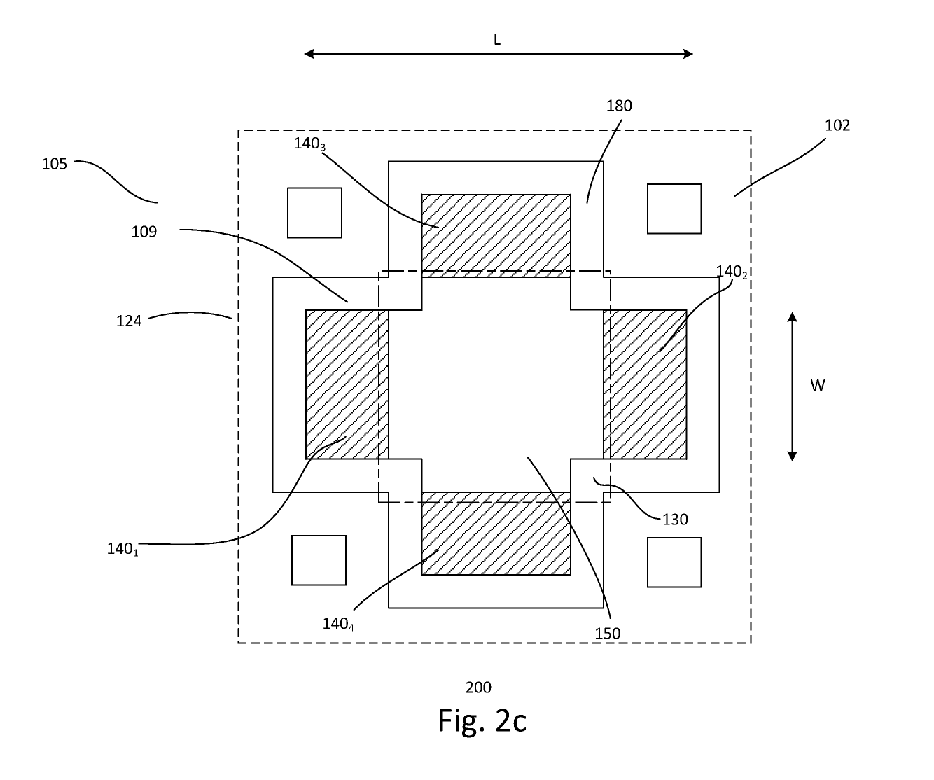

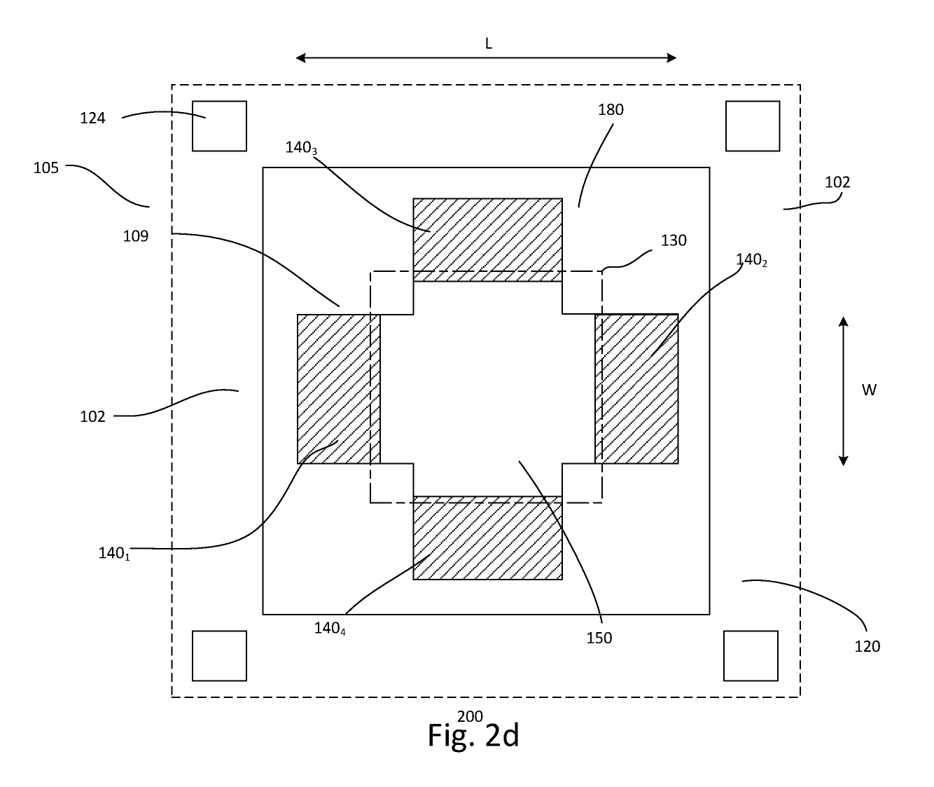

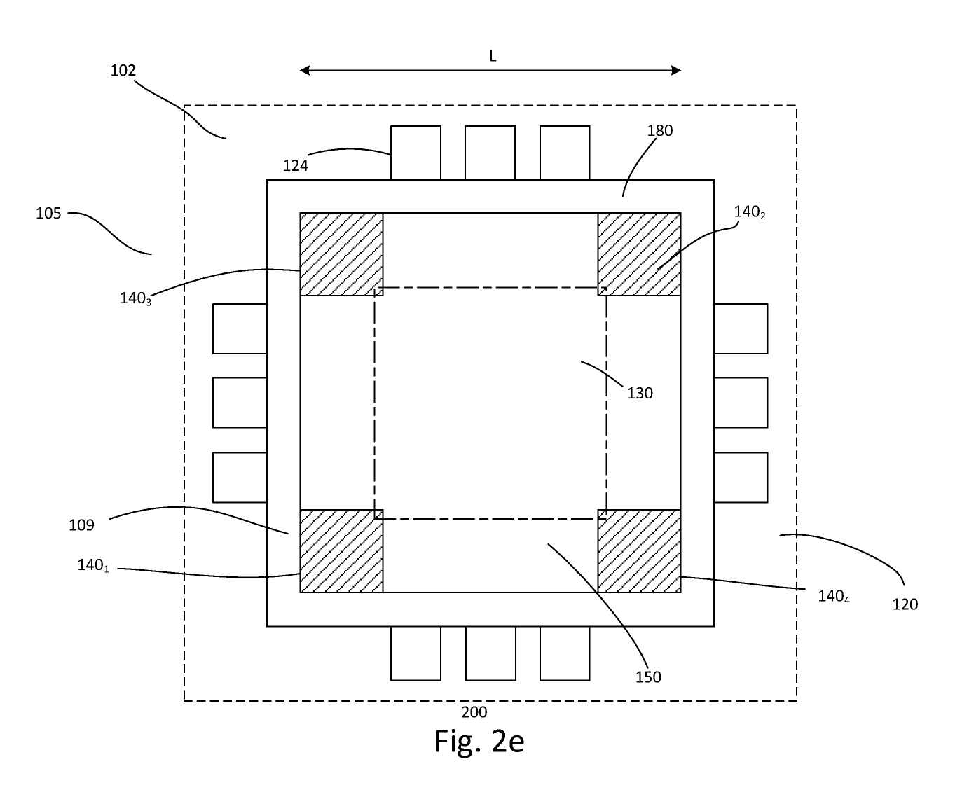

FIGS. 2a-2b show top and cross-sectional views of another embodiment of a device 200. The device is similar to the device shown in FIGS. 1a-1e. Common elements may not be described or described in detail.

The device includes a substrate, such as a crystal-on-insulator (COI) substrate. The COI substrate may be a silicon-on-insulator (SOI) substrate. The SOI substrate includes a buried oxide (BOX) layer 107 between a silicon bulk substrate 105 and a silicon surface substrate 109. The substrates can be intrinsic or lightly doped, for example, with p-type dopants.

As shown, the substrate includes a sensor region. The sensor region is configured for a Hall effect sensor 102. The sensor region occupies the surface substrate and the bulk substrate. The substrate may include other device regions. For example, the substrate includes complementary metal oxide semiconductor (CMOS) regions. The CMOS regions may occupy the substrate outside of the sensor regions. The substrate may also include a sensor hybrid region 108 to expose the bulk sensor region.

As shown, the sensor includes a Hall plate 150. The Hall plate is part of the surface substrate. The Hall plate, in one embodiment, has a cross shape or footprint. The Hall plate may be an undoped or an intrinsic Hall plate. Alternatively, the Hall plate may be doped with Hall plate dopants. In one embodiment, the Hall plate dopants are first polarity type dopants. First, second, third and fourth terminals or taps 1401, 1402, 1403 and 1404 are disposed at or near the ends of the Hall plate segments. The terminals are doped regions. In one embodiment, the terminals are heavily doped with terminal dopants. The terminal dopants may be first polarity type dopants.

A gate 130 is disposed on the surface substrate in the surface sensor region. The gate includes a gate electrode 134 over a gate dielectric 132. The gate electrode may be a polysilicon gate electrode and the gate dielectric may be a thermal oxide layer. Other types of gate layers may also be useful. Sidewall dielectric spacers 138 are disposed on sidewalls of the gate. A sidewall spacer may be a silicon oxide or a silicon nitride spacer. Alternatively, a spacer may be a stacked spacer having a plurality of dielectric layers. Regarding the gate electrode layer, it may be a doped gate electrode layer. The gate electrode layer may be doped with gate electrode dopants, which may be first or second polarity type dopants.

As shown, the gate overlaps the terminals of the sensor. The terminals, for example, may include heavily doped terminal regions and lightly doped extension terminal regions. The lightly doped regions, for example, extend under the gate while the heavily doped regions are aligned with the spacers. The gate electrode may be doped with second polarity type dopants. The gate electrode is coupled to a gate bias voltage. The terminal regions and the gate electrode may include metal silicide contacts.

A surface substrate trench isolation 180 is disposed in the surface substrate. The trench isolation region surrounds the Hall plate. The trench isolation region defines the surface sensor region on the surface substrate and BOX layer. The trench isolation region, as shown, extends from a surface of the surface substrate and into the bulk substrate. The top surface of the trench isolation region may be coplanar with the top surface of the surface substrate. The surface substrate and BOX layer beyond the trench isolation are removed to expose the surface of the bulk substrate.

A hybrid sensor trench isolation region 181 is disposed in the bulk substrate. The hybrid sensor trench isolation region surrounds the bulk sensor region in the bulk substrate. As shown, the sensor region in the bulk substrate has a larger footprint than the sensor region in the surface substrate. A sensor well 120 is provided in the bulk sensor region. The sensor well is doped with sensor well dopants. In one embodiment, the sensor well dopants are second polarity type dopants. As shown, the sensor well extends under the hybrid sensor trench isolation region. Sensor taps 124 are provided. As shown, the sensor taps are disposed adjacent to the ends of the segments of the Hall plate. The exemplary embodiment illustrates 3 well taps disposed in the bulk substrate adjacent to ends of the segments. The well taps, for example, are aligned with the surface substrate isolation region. The sensor taps are heavily doped with well tap dopants. The well tap dopants are the same polarity type as the sensor well dopants.

As described, a gate electrode is provided over the Hall plate and a sensor well is provided in the bulk substrate below the sensor plate. The gate and sensor well can be biased with appropriate gate bias and well bias voltages to vary the thickness of the Hall plate to a thickness less than the pre-defined thickness. As such, the thickness of the Hall plate can be varied by adjusting the bias voltages on the sensor well and gate to produce the desired sensitivity.

FIGS. 2c-2e show top views of other embodiments of a Hall sensor. The top views are similar to the top views of FIGS. 1c-1e. Common elements may not be described are described in detail. The various top views include a gate 130 disposed over the Hall plate 150. Providing a gate over the Hall plate enables varying the thickness of the Hall plate from the top and bottom.

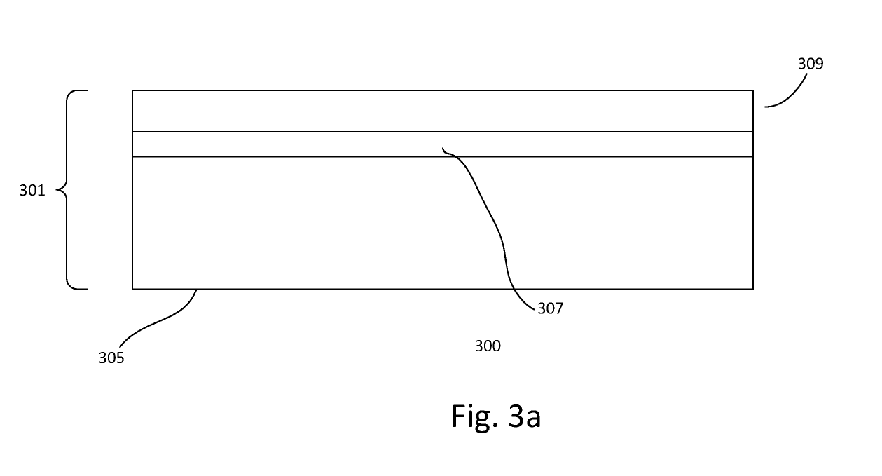

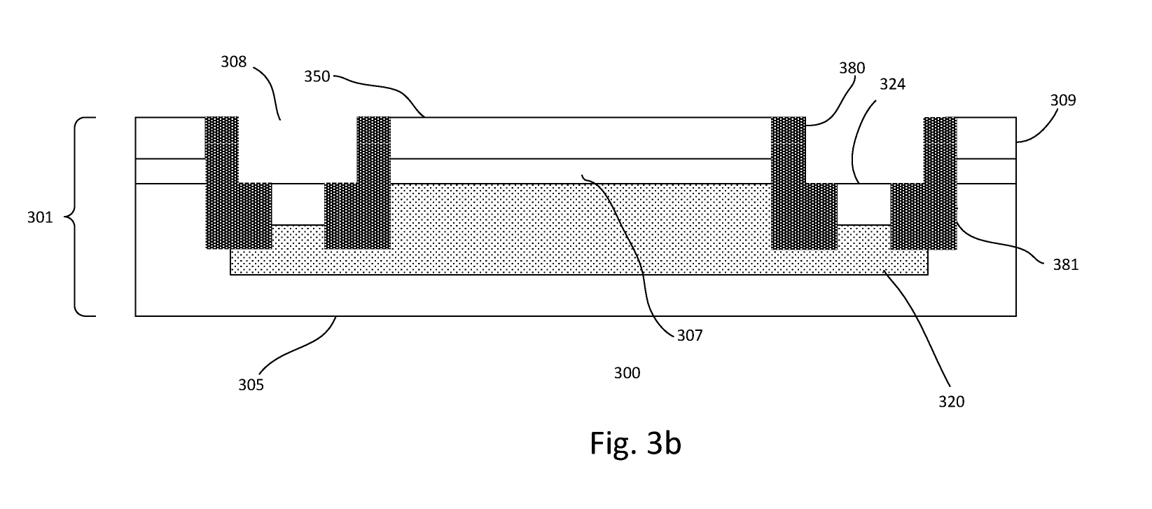

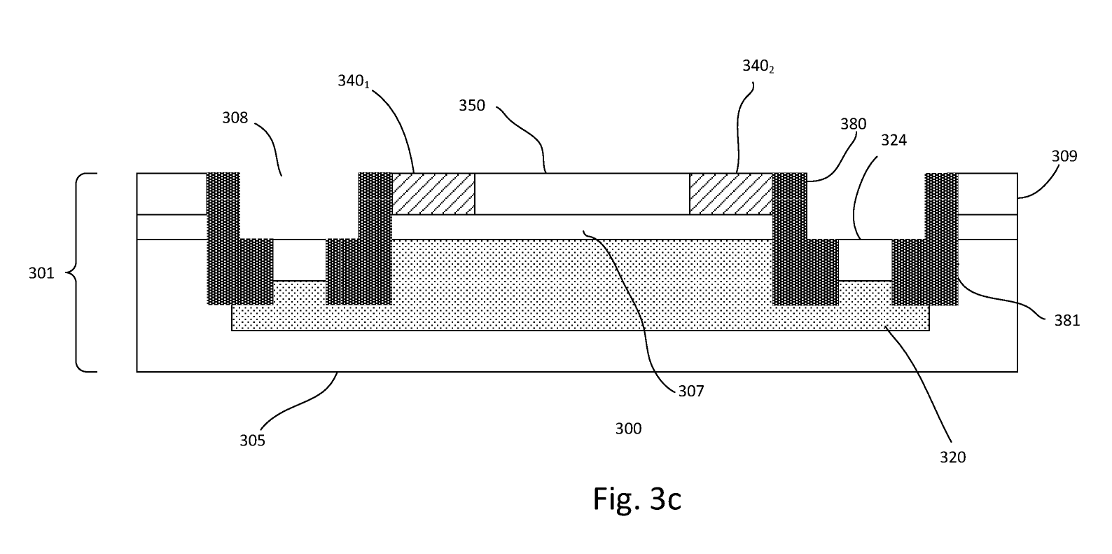

FIGS. 3a-3c show cross-sectional views of an embodiment of a process for forming a device 300. The device, for example, is similar to that described in FIGS. 1a-1e. Common elements may not be described or described in detail. Referring to FIG. 3a, a substrate 301 is provided. In one embodiment, the substrate is a crystal-on-insulator (COI) substrate, such as a silicon-on-insulator (SOI) substrate. The SOI substrate includes a buried oxide (BOX) layer 307 between a bulk silicon substrate 305 and a surface silicon substrate 309. The substrates can be intrinsic or lightly doped, for example, with p-type dopants. Providing substrates with other types of dopants or dopant concentrations may also be useful.

As shown in FIG. 3b, the substrate is processed to define a surface sensor region in the surface substrate and a hybrid region 308. In one embodiment, surface sensor trench isolation region 380 and hybrid sensor isolation region 381 are formed. Other trench isolation regions, such as CMOS trench isolation regions for CMOS regions may also be formed. The surface sensor trench isolation region defines a Hall plate 350 on the surface substrate. As for the hybrid trench isolation region, it defines a hybrid sensor region. Various trench isolation processes may be employed to form the surface trench isolation region. For example, the substrate can be etched using etch and mask techniques to form an isolation trench which is then filled with dielectric materials, such as silicon oxide. Chemical mechanical polishing (CMP) can be performed to remove excess oxide and provide a planar substrate top surface. Other processes or materials can also be used to form the trench isolation region. As shown, the trench isolation region extends into the bulk substrate.

In some embodiments, a hard mask may be employed to etch the substrate to form trenches. The hard mask may include a nitride layer over a pad oxide layer. Other types of hard masks may also be useful. The hard mask is patterned to expose the substrate to be etched. An etch forms the trenches in the substrate exposed by the hard mask. After filling the trenches with a dielectric fill material, such as tetraethyl orthosilicate (TEOS), a CMP is performed to provide a planar surface with the fill material and the pad oxide. The pad oxide may be subsequently removed, leaving the isolation regions having a height above the substrate.

The surface substrate and BOX layer are patterned to form a hybrid sensor region 308. The surface substrate and BOX layer may be patterned using mask and etch processes. For example, an anisotropic etch, such as a RIE or dry etch, etches the surface substrate and BOX layer using patterned photoresist mask. The etch exposes the bulk substrate, forming the hybrid region. The process may also form CMOS hybrid regions to expose the bulk substrate in the CMOS regions. As already discussed, the CMOS regions may include both hybrid and non-hybrid CMOS regions.

A sensor well 320 may be formed in the bulk substrate in the bulk sensor region. The sensor well is doped with sensor well dopants. The sensor well dopants may be second polarity type dopants. To form the sensor well, sensor well dopants are implanted into the substrate using an implant mask with an opening corresponding to the sensor well region provided in the surface substrate. The energy of the implant is sufficient to form the sensor well in the bulk substrate. The sensor well may be lightly or intermediately doped with sensor well dopants. The implant mask is removed after forming the sensor well. The sensor well may be formed prior to forming the trench isolation regions. Forming the sensor well subsequent to forming the trench isolation regions may also be useful. In some embodiments, the sensor well is formed later in the process flow.

The Hall plate may be doped with Hall dopants. The Hall dopants may be first polarity type dopants. The Hall plate may be doped by implanting Hall dopants into the surface substrate using an implant mask. For example, the implant mask includes an opening corresponding to the Hall plate, enabling dopants to be implanted into the Hall plate.

Referring to FIG. 3c, the substrate is processed. In one embodiment, standard logic processes are performed on the sensor and CMOS regions of the substrate. The process may include forming transistor wells in the CMOS regions of the substrate. The transistor wells may include p-type and n-type transistor wells formed using separate implant processes. In some cases, the transistor well implant may be employed to form the sensor well. For example, the appropriate polarity type dopants are implanted to form both the transistor and sensor wells. Forming the transistor wells and sensor well in separate implant processes may also be useful.

Gate layers, such as gate dielectric and gate electrode layers, may be formed on the substrate. The gate dielectric layer may be a thermal oxide layer while the gate electrode layer may be a polysilicon layer. Other types of gate layers may also be useful. The gate layers are patterned to form gates in the transistor regions. The gate layers may be patterned using mask and etch processes. After forming the gates, lightly doped source/drain (S/D) extension regions are formed adjacent to the gates. For example, p-type S/D extension regions are formed for p-type transistors and n-type S/D extension regions are formed form n-type transistors. The p-type and n-type S/D extension regions may be formed by implanting p-type and n-type dopants using separate implant processes. The lightly doped extension implant may also be used to dope the sensor well taps and sensor terminals. For example, appropriate polarity type dopants may be used to form the lightly doped extension regions, and may also be employed to form well taps and sensor terminals.

Gate sidewall spacers may be formed on the gate sidewalls. In one embodiment, a spacer dielectric layer, such as silicon oxide, lines the substrate surface and gates. An anisotropic etch, such as RIE, is performed to remove horizontal portions of the spacer layer, leaving spacers remaining on the gate sidewalls. Heavily doped S/D regions may be formed adjacent to the gates. P-type and n-type heavily doped S/D regions may be formed by implanting p-type and n-type dopants using separate implant processes.

In one embodiment, the S/D implants are also employed to form the Hall plate terminals 3401, 3402, 3403 and 3404 as well as well taps 324. For example, appropriate polarity type S/D implant or implants may be used to form the Hall plate terminals and well taps. Other configuration of forming the Hall plate terminals and well taps may also be useful.

The process continues to complete the device. The process may include an anneal, such as a rapid thermal anneal (RTA) to activate the dopants implanted into the substrate. Silicide contacts may be formed on the contact regions. To form silicide contacts, a metal layer is formed over the substrate and annealed to cause a reaction with the exposed crystalline substrate. An oxide or nitride layer may be formed over the Hall plate, except in the terminal regions, to prevent silicidation. The unreacted metal may be removed by a wet etch, leaving silicide contacts over the contact regions.

A first contact dielectric layer may be formed over the substrate. The contact dielectric layer serves as the first contact level of the back-end-of-line (BEOL) dielectric layer. Contacts are formed in the first contact dielectric layer. The contacts may be tungsten contacts formed by a damascene process. For example, via openings are formed in the first dielectric layer and filled with contact material. Excess contact material is removed by CMP, forming the contacts in the first dielectric layer.

Additional BEOL processing may be performed, such as forming the first metal level and additional ILD levels which include via and metal levels and pad level, passivation, pad opening, as well as other processes. After processing, the wafer is diced to separate the devices into individual devices.

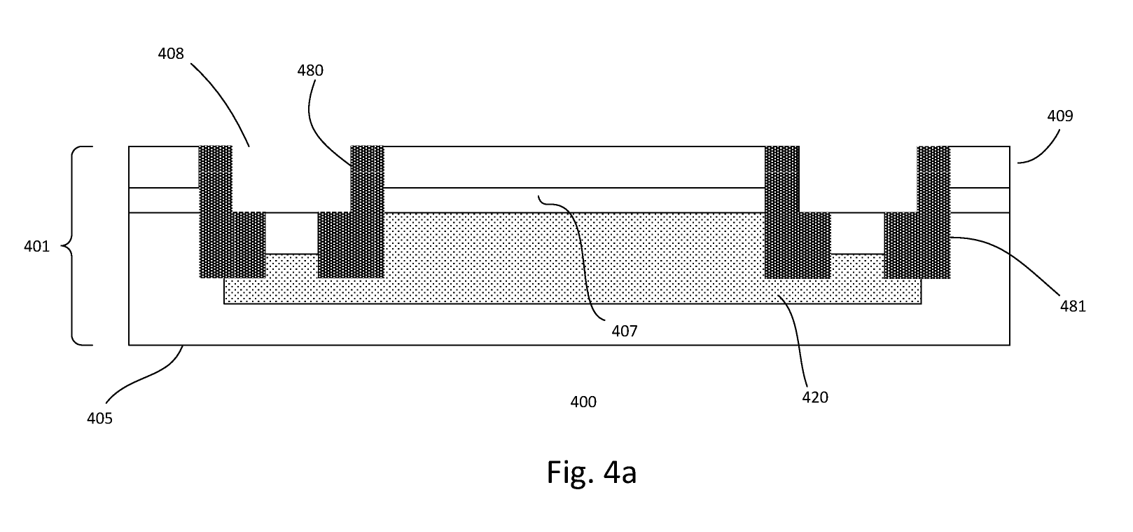

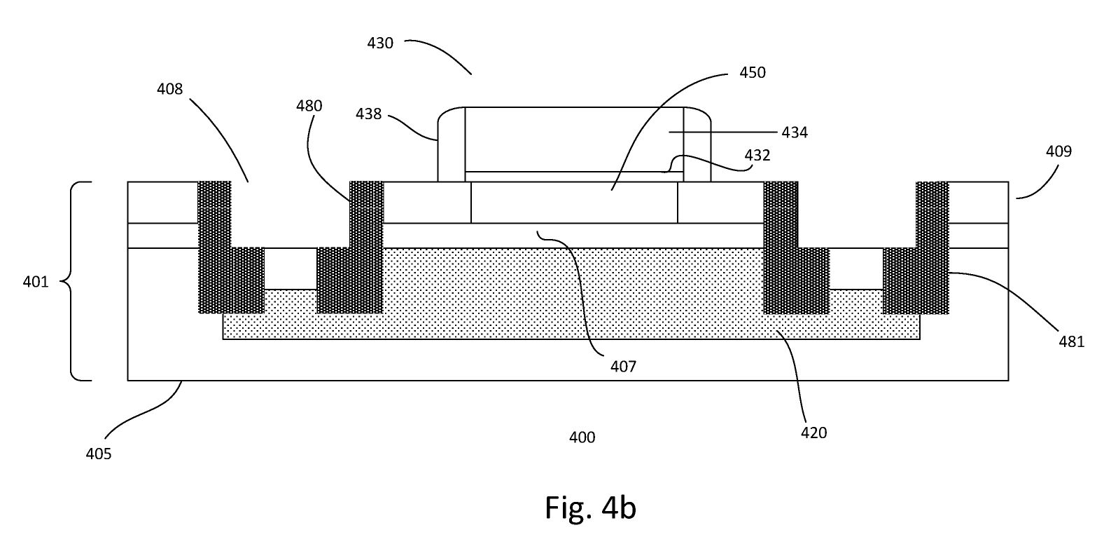

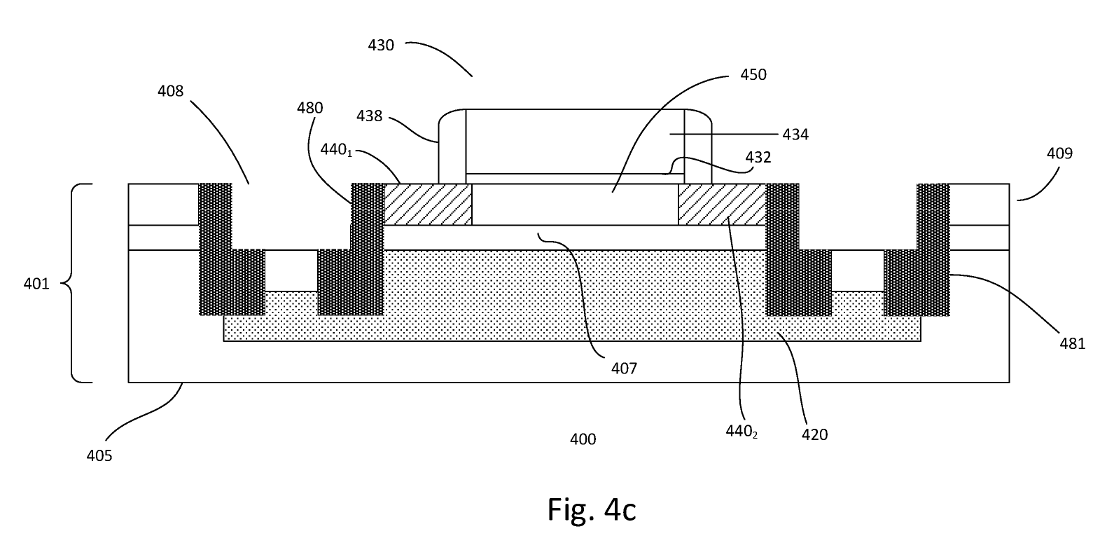

FIGS. 4a-4c show cross-sectional views of another embodiment of a process for forming a device 400. The device, for example, is similar to that described in FIGS. 2a-2e and FIGS. 3a-3c. Common elements may not be described or described in detail. Referring to FIG. 4a, a substrate 401 is provided. The substrate is a SOI substrate having a BOX layer 407 between a surface silicon layer 409 and a bulk silicon layer 405. The substrate is processed to the stage as described in FIG. 3b. For example, the substrate is defined with a surface sensor region, a bulk sensor region and a hybrid sensor region 408. The surface sensor trench isolation region defines the surface sensor region and the hybrid trench isolation region 481 defines the hybrid region and bulk sensor region. A sensor well 420 may be formed in the bulk substrate.

Referring to FIG. 4b, the substrate is processed. In one embodiment, standard logic processes are performed on the sensor and CMOS regions of the bulk substrate. The process may include forming transistor wells in the CMOS regions of the substrate. The transistor wells may include p-type and n-type transistor wells formed using separate implant processes. In some cases, the transistor well implant may be employed to form the sensor well. For example, the appropriate polarity type dopants are implanted to form both the transistor and sensor wells. Forming the transistor wells and sensor well in separate implant processes may also be useful.

Gate layers, such as gate dielectric and gate electrode layers, may be formed on the substrate. The gate dielectric layer may be a thermal oxide layer while the gate electrode layer may be a polysilicon layer. Other types of gate layers may also be useful. The gate layers are patterned to form gates in the transistor regions. The gate layers may be patterned using mask and etch processes. The gate layers may be patterned using mask and etch processes. In one embodiment, a sensor gate 430 is formed over the Hall plate in the surface sensor region. The sensor gate, as shown, includes a gate electrode layer 434 over a gate dielectric layer 432.

After forming the gates, lightly doped source/drain (S/D) extension regions are formed adjacent to the gates. For example, p-type S/D extension regions are formed for p-type transistors and n-type S/D extension regions are formed form n-type transistors. The p-type and n-type S/D extension regions may be formed by implanting p-type and n-type dopants using separate implant processes. The lightly doped extension implant may also be used to dope the sensor well taps and sensor terminals. For example, appropriate polarity type dopants may be used to form the lightly doped extension regions, and may also be employed to form well taps and sensor terminals.

Gate sidewall spacers 438 may be formed on the gate sidewalls. Heavily doped S/D regions may be formed adjacent to the gates. P-type and n-type heavily doped S/D regions may be formed by implanting p-type and n-type dopants using separate implant processes.

In one embodiment, the S/D implants are also employed to form the Hall plate terminals 440₁, 440₂, 440₃ and 440₄ as well as well taps 424, as shown in FIG. 4c. For example, appropriate polarity type S/D implant or implants may be used to form the Hall plate terminals and well taps. Other configuration of forming the Hall plate terminals and well taps may also be useful. The process continues to complete the device, as already described.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

1. A device comprising:
a crystalline-on-insulator (COI) substrate having
a bulk crystalline substrate,
a surface crystalline substrate, and
a buried oxide layer disposed between the bulk and surface crystalline substrates;
a sensor region, the sensor region having
a surface sensor region disposed on the surface crystalline substrate, and
a bulk sensor region disposed on the bulk crystalline substrate; and
a Hall effect sensor disposed in the sensor region, the Hall effect sensor comprises
a Hall plate in the surface sensor region, the Hall plate is part of the surface crystalline substrate, the Hall plate comprises
first and second current terminals, the Hall plate is configured to flow current through the Hall plate between the first and second current terminals in a length direction of the Hall plate,
first and second sensing terminals, the first and second sensing terminals are configured to sense a Hall voltage Vu along a width direction of the Hall plate,
wherein the length and width directions are perpendicular directions, and
wherein a predetermined thickness of the Hall plate is determined by a thickness of the surface crystalline substrate,
a sensor well, the sensor well is disposed in the bulk sensor region in the bulk crystalline substrate, and
a sensor well tap in the sensor well, the sensor well tap is coupled to a sensor well bias voltage for biasing the sensor well for varying a thickness of the Hall plate from the predetermined thickness of Hall plate to tune the sensitivity of the Hall effect sensor.

2. The device of claim 1 wherein the Hall plate comprises a cross shape, wherein:
the current terminals are disposed on opposing ends segments of the cross along a length direction; and
the sensor terminals are disposed on opposing ends of segments of the cross along a width direction.

3. The device of claim 1 wherein the Hall plate comprises a rectangular shape, wherein
the current terminals are disposed on a first set of diagonal corners of the rectangular shaped Hall plate along a length direction; and
the sensor terminals are disposed on a second set of diagonal corners of the rectangular shaped Hall plate along a width direction.

4. The device of claim 1 wherein a length of the Hall plate is between the current terminals.

5. The device of claim 1 wherein the current terminals and sensor terminals are interchangeable with time during operation.

6. The device of claim 1 wherein the device comprises a hybrid sensor region, the hybrid sensor region exposes the bulk sensor region in which the well tap is disposed.

7. The device of claim 6 wherein the hybrid sensor region is defined by:
a sensor trench isolation region which surrounds the Hall plate; and
a hybrid trench isolation region.

8. The device of claim 7 wherein the sensor trench isolation region and the hybrid trench isolation region extend from a top of the surface substrate and into a predefined isolation depth in the bulk substrate.

9. The device of claim 1 comprises a gate disposed over the Hall plate, the gate comprises a gate electrode over a gate dielectric layer which is disposed over the Hall plate.

10. The device of claim 9 wherein the gate comprises a rectangular shape, wherein:
the current terminals serve as a first set of source/drain (S/D) terminals in a length direction; and
the sensing terminals serve as a second set of S/D terminals in a width direction.

11. The device of claim 10 wherein the gate is coupled to a gate bias voltage for varying the thickness of the Hall plate from the predetermined thickness from a top of the Hall plate to tune the sensitivity of the Hall effect sensor.

12. The device of claim 9 wherein the current terminals and sensor terminals are interchangeable with time during operation.

13. A method of forming a device comprising:
providing a crystalline-on-insulator (COI) substrate having
a bulk crystalline substrate,
a surface crystalline substrate, and
a buried oxide layer disposed between the bulk and surface crystalline substrates;
preparing a sensor region, the sensor region having
a surface sensor region disposed on the surface crystalline substrate, and
a bulk sensor region disposed on the bulk crystalline substrate; and
forming a Hall effect sensor in the sensor region, wherein forming the Hall effect sensor comprises
forming a Hall plate in the surface sensor region, the Hall plate is part of the surface crystalline substrate, the Hall plate comprises
first and second current terminals, the Hall plate is configured to flow current through the Hall plate between the first and second current terminals in a length direction of the Hall plate, and
first and second sensing terminals, the first and second sensing terminals are configured to sense a Hall voltage Vu along a width direction of the Hall plate,
wherein the length and width directions are perpendicular directions, and
wherein a predetermined thickness of the Hall plate is determined by a thickness of the surface crystalline substrate,
forming a sensor well in the bulk sensor region in the bulk crystalline substrate, and
forming a sensor well tap in the sensor well, the sensor well tap is coupled to a sensor well bias voltage for biasing the sensor well for varying a thickness of the Hall plate from the predetermined thickness of the Hall plate to tune the sensitivity of the Hall effect sensor.

14. The method of claim 13 wherein forming the Hall plate comprises forming a cross shaped Hall plate, and wherein:
the current terminals are formed opposing ends segments of the cross along a length direction; and
the sensor terminals are disposed on opposing ends of segments of the cross along a width direction.

15. The method of claim 13 wherein forming the Hall plate comprises forming a rectangular shaped Hall plate, and wherein:
the current terminals are disposed on a first set of diagonal corners of the rectangular shaped Hall plate along a length direction; and
the sensor terminals are disposed on a second set of diagonal corners of the rectangular shaped Hall plate along a width direction.

16. The method of claim 13 wherein the current terminals and sensor terminals are interchangeable with time during operation.

17. The method of claim 13 wherein the sensor region comprises:
forming a surface sensor trench isolation region to define the surface sensor region; and
forming a hybrid sensor trench isolation region, wherein the hybrid sensor region defines the bulk sensor region,
a hybrid region disposed between the surface sensor region and bulk sensor region, and
wherein the hybrid region exposes the bulk substrate for accessing the well tap.

18. The method of claim 13 comprises forming a gate disposed over the Hall plate, wherein the gate comprises a gate electrode over a gate dielectric layer, the gate dielectric layer is formed over the Hall plate.

19. The method of claim 18 wherein:
forming the gate comprises forming a rectangular shaped gate, wherein
the current terminals serve as a first set of source/drain (S/D) terminals in a length direction;
the sensing terminals serve as a second set of S/D terminals in a width direction; and
coupling a gate bias voltage for varying the thickness of the Hall plate from the predetermined thickness from a top of the Hall plate to tune the sensitivity of the Hall effect sensor.

20. A device comprising:
a crystalline-on-insulator (COI) substrate having
a bulk crystalline substrate,
a surface crystalline substrate, and
a buried oxide layer disposed between the bulk and surface crystalline substrates;
a sensor region, the sensor region having
a surface sensor region disposed on the surface crystalline substrate, and
a bulk sensor region disposed on the bulk crystalline substrate;
a Hall effect sensor disposed in the sensor region, the Hall effect sensor comprises
a Hall plate in the surface sensor region, the Hall plate is part of the surface crystalline substrate, the Hall plate comprises
first and second current terminals, the Hall plate is configured to flow current through the Hall plate between the first and second current terminals in a length direction of the Hall plate,
first and second sensing terminals, the first and second sensing terminals are configured to sense a Hall voltage Vu along a width direction of the Hall plate,
wherein the length and width directions are perpendicular directions, and
wherein a predetermined thickness of the Hall plate is determined by a thickness of the surface crystalline substrate,
a sensor well disposed in the bulk sensor region in the bulk crystalline substrate, and
a sensor well tap in the sensor well, the sensor well tap is coupled to a sensor well bias voltage for biasing the sensor well for varying a thickness of the Hall plate from the predetermined thickness of Hall plate to tune the sensitivity of the Hall effect sensor; and
a gate disposed on the Hall effect sensor, wherein the gate is coupled to a gate bias voltage for varying the thickness of the Hall plate from the predetermined thickness from a top of the Hall plate to tune the sensitivity of the Hall effect sensor.
